(19) United States
(12) Patent Application Publication
(10) Pub. No.: US 2026/0312369 A1
(43) Pub. Date: Oct. 8, 2026

(54) SEMICONDUCTOR OPTICAL AMPLIFIER FOR LASER DEVICES, PARTICULARLY OF THE QUANTUM CASCADE TYPE, AND LASER DEVICE COMPRISING SAID OPTICAL AMPLIFIER

(71) Applicant: PJFC SEMICONDUCTORS SOCIETA' A RESPONSABILITA' LIMITATA SEMPLIFICATA, Castiglione delle Stiviere (IT)

(72) Inventor: Lodovico ROSSI, Castiglione delle Stiviere (IT)

(21) Appl. No.: 18/996,670

(22) PCT Filed: Jul. 31, 2023
(86) PCT No.: PCT/IB2023/057753

§ 371 Date: Jan. 17, 2025

(30) Foreign Application Priority Data
Aug. 2, 2022 (IT) 102022000016356

(51) Int. Cl. H01S 5/34; H01S 5/30

(52) U.S. Cl. CPC H01S 5/3402; H01S 5/3077

(57) ABSTRACT

A semiconductor optical amplifier for laser devices, particularly of the quantum cascade type, which is adapted to emit luminous radiation when subjected to an electric current and which comprises: a quantum well structure, composed of high bandgap layers alternated with low bandgap layers, which is interposed between a lower contact layer and an upper contact element; input electrical conduction elements and output electrical conduction elements which are configured to allow the flow of an electric current through the quantum well structure, and further comprising a silicon-on-insulator substrate which comprises an upper layer of crystalline silicon, such upper layer of silicon constituting the lower contact layer; the high bandgap layers are made of a material chosen among oxides and nitrides of the following materials: silicon (Si), titanium (T), aluminum (Al), hafnium (Hf), tantalum (Ta).

The present invention relates to a semiconductor optical amplifier for laser devices, in particular of the quantum cascade type, and a laser device that comprises such optical amplifier.

As is known, lasers are devices designed to emit a beam of substantially coherent and substantially monochromatic light (commonly known as a laser beam), by taking advantage of the phenomenon of stimulated emission.

Very generally, every laser comprises an active element, or optical amplifier, which is adapted to emit luminous radiation (photons) when suitably energetically stimulated by way of a system called pumping. This active element is included in an optical resonant cavity or optical resonator. The portion of radiation that exits from the resonator forms the laser beam, while the portion of radiation that remains confined in the resonator contributes to feeding the emission stimulated in the active element via a feedback mechanism.

As is known, in semiconductor lasers the active element that emits light is constituted by a semiconductor structure, and the pumping system usually consists in the application of an electric current to the semiconductor structure, through electrical contacts, so as to generate an electric current in the optical amplifier proper.

In semiconductor lasers, the optical resonator is obtained with various known techniques, for example by providing a pair of reflective surfaces opposite the two opposite sides of the active element so as to obtain what is known as a Fabry-Pérot cavity, or with other systems such as a distributed Bragg reflector (DBR), a distributed feedback system (DFB), ring resonators, etc.

In semiconductor lasers of the conventional type, the optical amplifier is a P-N junction diode (composed of composite semiconductors, typically GaAs or InP) and the active region of the structure, from which the laser radiation is emitted, is the junction region of the diode.

The optical power is therefore generated by applying a direct current to the junction: in such conditions an electron that is in the conduction band can recombine with a hole present in the valence band, giving rise to a photon whose wavelength λ depends on the “band-gap energy” BGE (i.e. the energy jump between the conduction band and the valence band).

Semiconductor lasers are also known which are called “quantum cascade” lasers, and are described for example in Faist J., “Quantum Cascade Lasers” (2013).

In quantum cascade lasers, the optical emission is due to a single type of carrier (typically the electron) and therefore a p-n junction is no longer necessary: the photons are emitted not via the electron-hole recombination mechanism, but by way of a continuous “fall” of an electron (whence the name quantum cascade) from a higher energy level to a lower energy level within the active part of the semiconductor optical amplifier.

In order to obtain this effect, the semiconductor optical amplifier of a quantum cascade laser comprises a “quantum well” structure which basically constitutes the active portion of the optical amplifier. In this structure the states of the electrons are confined in the quantum wells.

In more detail, this structure is composed of a series of high and low bandgap layers, mutually alternated: layers of low bandgap material (quantum wells) alternated with layers of high bandgap material (barriers).

In conventional quantum cascade lasers, such an optical amplifier comprising the quantum well structure is composed of composite semiconductor materials of III-V type, that is to say composed of elements from group III (boron, aluminum, gallium, indium) and from group V (nitrogen, phosphor, arsenic, antimony, bismuth), such as for example indium phosphide (InP) and optional ternary or quaternary compounds.

These conventional semiconductor lasers, although very useful and advantageous under several viewpoints, have a number of drawbacks and aspects with room for improvement, which include the high costs of materials and of production.

In particular, conventional quantum cascade lasers have a high cost which is due to the use of rare materials.

Furthermore, conventional semiconductor lasers based on materials III-V have a high level of complexity of manufacture in that they cannot be produced using standard processes in traditional electronics. In particular, to integrate these conventional lasers on silicon it is necessary to bond “slices” of different material in post-production.

Another aspect with room for improvement in conventional quantum cascade lasers relates to the spectrum of possible emission wavelengths: it is in fact desirable to increase this spectrum and, in particular, the need is felt to obtain emission wavelengths that are compatible with current near-infrared telecommunications technologies.

Other aspects with room for improvement in conventional quantum cascade lasers relate to energy efficiency and the necessary threshold current to be applied to the optical amplifier to activate the laser effect.

The aim of the present invention is to provide a semiconductor optical amplifier, in particular of the quantum cascade type, that is capable of solving the above mentioned problems and overcoming the above mentioned limitations of the background art.

Within this aim, an object of the present invention is to provide a semiconductor optical amplifier that is simpler and/or more economic to make with respect to the background art.

Another object of the invention consists of providing a semiconductor optical amplifier that has a broad spectrum of emission wavelengths and if possible emission wavelengths that are compatible with current telecommunications technologies.

Another object of the invention consists of providing a semiconductor optical amplifier that has greater efficiency and/or greater versatility with respect to the background art.

This aim and these and other objects which will become more apparent hereinafter are achieved by a semiconductor optical amplifier for laser devices, in particular of the quantum cascade type, according to claim 1, optionally provided with the characteristics defined by the dependent claims.

This aim and these and other objects which will become better apparent hereinafter are also achieved by a laser device according to claim 14.

Further characteristics and advantages of the invention will become better apparent from the description of some preferred, but not exclusive, embodiments of an optical amplifier according to the invention and of a laser device that comprises such optical amplifier, which are illustrated by way of non-limiting example with the aid of the accompanying drawings wherein:

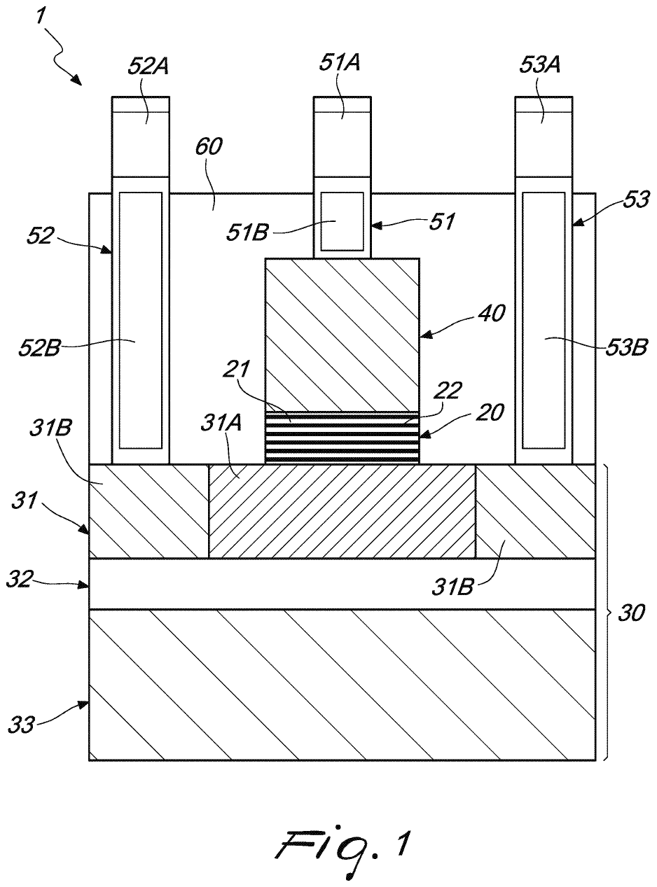

FIG. 1 is a schematic diagram, in a cross-sectional view taken along a vertical plane, of a generic embodiment of an optical amplifier according to the invention;

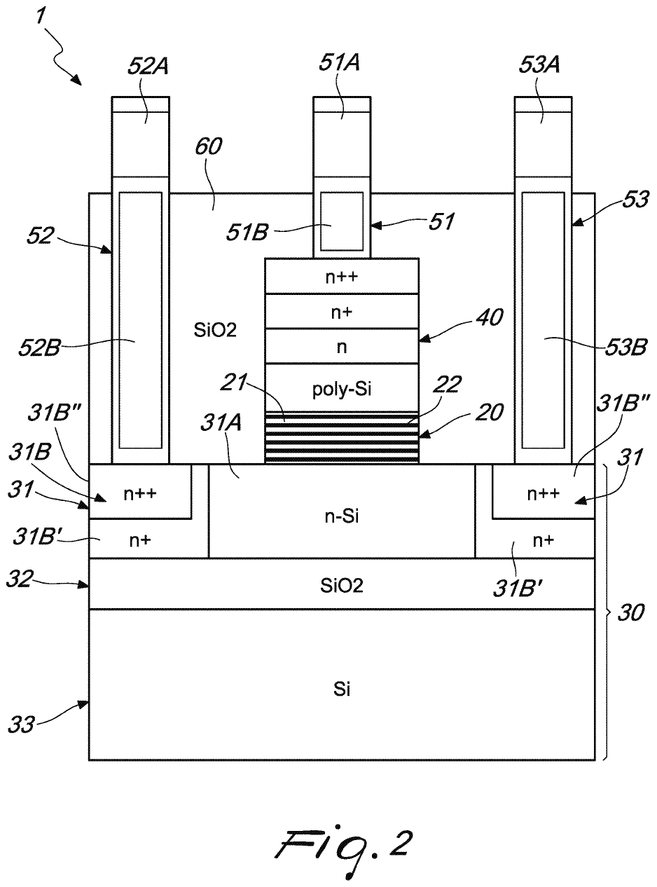

FIG. 2 is a schematic diagram, in a cross-sectional view taken along a vertical plane, of a particular preferred embodiment of the optical amplifier, in which the materials used are also indicated;

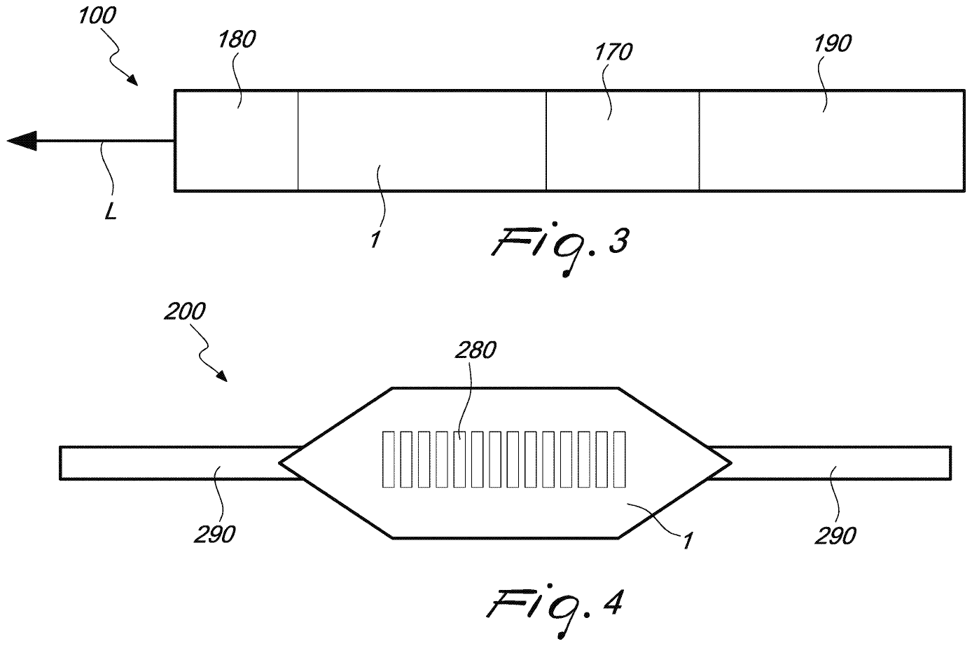

FIG. 3 is a schematic diagram of a first possible embodiment of a laser device that comprises the optical amplifier;

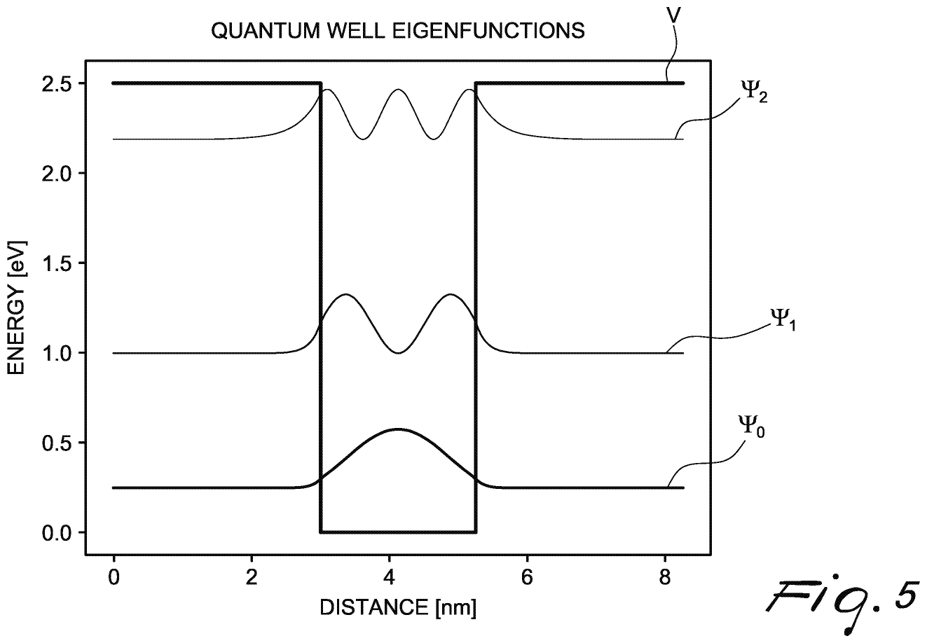

FIG. 4 is a schematic diagram of a second possible embodiment of a laser device that comprises the optical amplifier;

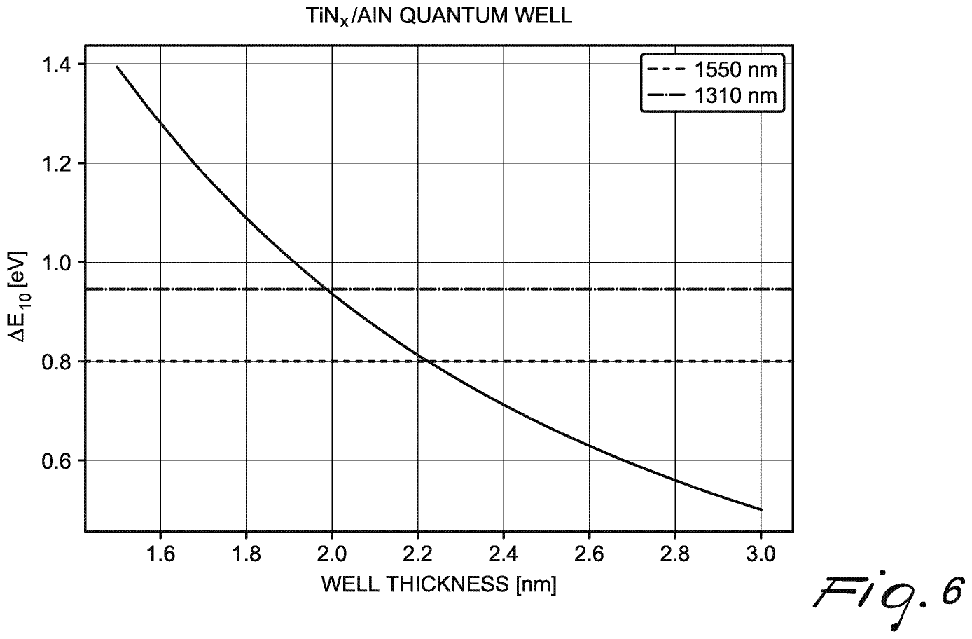

FIG. 5 is a diagram representing the simulated eigenfunctions of an electron in a quantum well of titanium nitride associated with barriers of aluminum nitride, in a quantum well structure of an optical amplifier according to the invention (the graph shows the squared modulus |Ψᵢ|² of the indicated eigenfunctions);

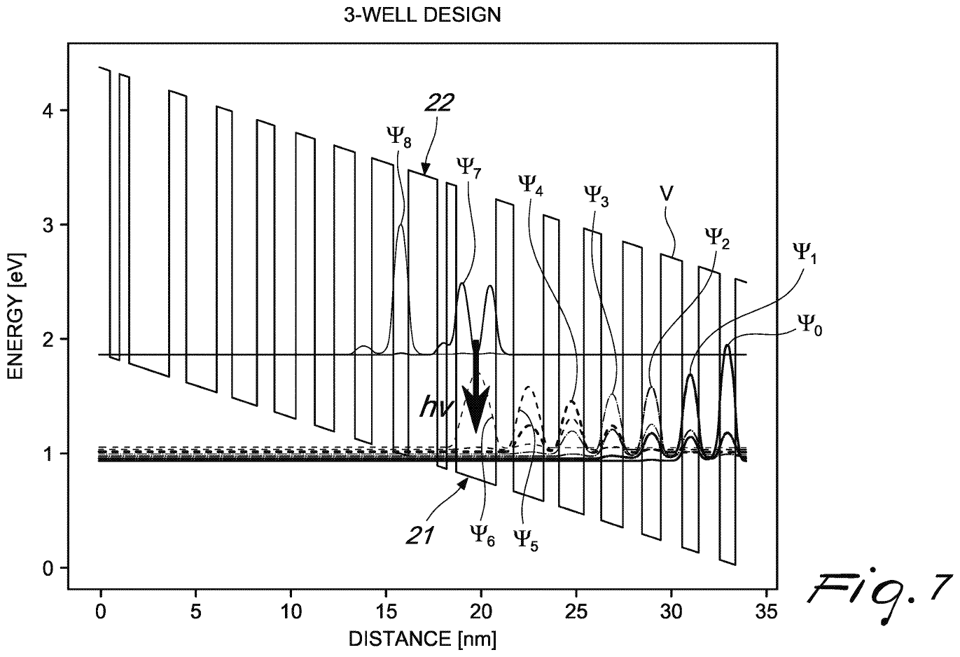

FIG. 6 is a diagram representing the transition energy between the first and the second confined state, i.e. the energy of the emitted photon, as a function of the thickness of a quantum well of titanium nitride with barriers of aluminum nitride, in a quantum well structure of an optical amplifier according to the invention;

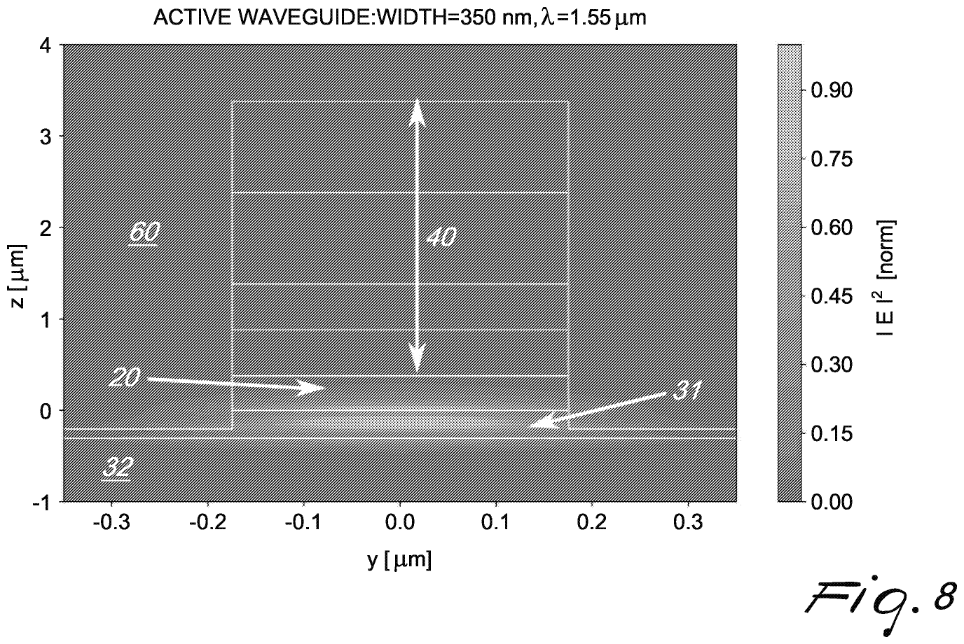

FIG. 7 is a graph showing the minibands with photon emission in the quantum well structure of a preferred embodiment of the optical amplifier (the graph represents the squared modulus |Ψᵢ|² of the indicated eigenfunctions);

FIG. 8 is a graph showing the flat cross-section of part of the optical amplifier of the previous figure, with graphic indication the intensity of the electrical field during the operation.

FIGS. 1-4 are purely schematic and therefore are not to scale.

With reference to the figures, the optical amplifier, generally designated by the reference numeral 1, is intended to act as the active element of a semiconductor laser device 100, 200, in particular of the quantum cascade type, and is adapted to emit a luminous radiation (photons) when subjected to an electric current having an intensity equal to or higher than a certain threshold value.

The term “luminous radiation” is used here to indicate, entirely generally, any electromagnetic radiation outside or outside the visible spectrum; in particular, in the preferred embodiments, the luminous radiation emitted by the optical amplifier 1 is in the infrared and more precisely in the near-infrared, this by virtue of the peculiar materials used, as will become better apparent below.

In other words, the optical amplifier 1 is adapted to constitute the “active medium” or gain medium of a laser 100, 200, in particular of a semiconductor quantum cascade laser.

The optical amplifier 1 is an active structure of the quantum cascade type and therefore it comprises a quantum well structure 20, that is to say a conveniently engineered structure, composed of high bandgap layers 21 (i.e. layers of barriers) alternated with low bandgap layers 22 (i.e. layers of quantum wells).

Such quantum well structure 20 is interposed between a lower contact layer 31 and an upper contact element 40 for the passage of electrons entering, and leaving, the quantum well structure 20.

The optical amplifier 1 further comprises input electrical conduction means 51 and output electrical conduction means 52, 53, which are conventional and are configured, in a known manner, according to the technologies typical of CMOS integration, in order to allow the flow of an electric current through the quantum well structure 20.

The electrical conduction means 51, 52, 53 are adapted to connect the optical amplifier 1, and in particular the quantum well structure 20, with an electrical circuit or in any case with an electrical current or voltage source so as to enable the generation of an electric current in the quantum well structure 20, with the electrons flowing from the input electrical conduction means 51 to the upper contact element 40, from there through the quantum well structure 20, and on to the lower contact layer 31 in order to then exit through the output electrical conduction means 52, 53. Conveniently, to this end, the electrical conduction means 51, 52, 53 have connecting ends 51A, 52A, 53A (which in practice define electrical contacts).

The electrical conduction means 51, 52, 53 can be provided in any known manner and preferably comprise, or consist of, lines or conduits of metal, preferably tungsten, and are conveniently provided with the above mentioned connecting ends 51A, 52A, 53A which constitute the upper contacts, preferably of aluminum or copper.

In the preferred and illustrated embodiments, the input conduction means 51 comprise, or consist of, a single line (or conduit) of metal connected to the upper contact element 40, while the output conduction means 52, 53 comprise, or consist of, two lines (or conduits) of metal, both of which are connected to the lower contact layer 31 and are arranged on opposite sides with respect to the quantum well structure 20.

According to the invention, the optical amplifier 1 comprises a silicon-on-insulator (SOI) substrate 30 which in turn comprises an upper layer of crystalline silicon 31, such upper layer of crystalline silicon 31 constituting the above mentioned lower contact layer 31.

Advantageously, the presence of the silicon-on-insulator substrate 30 makes it possible to obtain a passive waveguide for the radiation, by virtue of the difference in refractive index between the waveguide and the material that surrounds it. In practice the waveguide is formed by a central region 31A of the upper layer of crystalline silicon 31, as will become clearer below.

In more detail, in the silicon-on-insulator substrate 30, the upper layer of crystalline silicon 31 is overlaid on an insulating layer 32 (preferably also based on silicon and even more preferably made of silicon dioxide SiO₂) which is in turn overlaid on a lower layer of crystalline silicon (Si) 33.

Preferably, in order to limit optical losses, in the silicon-on-insulator substrate 30, the upper layer of crystalline silicon 31 comprises:
a central contact region 31A which is in contact with the quantum well structure 20, and
at least one peripheral region 31B which is adjacent to the central region 31A, which is in contact with the output electrical conduction means 52A, 52B and is constituted by n-doped silicon.

Conveniently, the central contact region 31A is also made of n-doped silicon having a minimum percentage of donor atoms that is lower than the percentage of donor atoms present in the at least one peripheral region 31B: such at least one peripheral region 31B comprises n-doped silicon having a percentage of donor atoms that is higher than the above mentioned minimum percentage.

According to an optional and advantageous characteristic (illustrated for example in FIG. 2), the at least one peripheral region 31B is also divided into regions with different doping, and more precisely a doping level n that increases toward the output electrical conduction means 52, 53. More precisely, the at least one peripheral region 31B comprises:
at least one first layer of n-doped silicon with a medium percentage of donor atoms 31B′ which is adjacent to the central region 31A, and
at least one second layer of n-doped silicon with a high percentage of donor atoms 31B″ which is adjacent to the output conduction means 52, 53.

In this manner an increasing doping gradient forms from the quantum well structure 20 toward the output conduction means 52, 53; this makes it possible to minimize the overlap with the optical mode that is propagated during operation.

With regard to the upper contact element 40, this can be constituted by one or more layers of metal, but preferably it is made of polycrystalline silicon (poly-Si).

In the preferred embodiments, including the embodiment shown in FIG. 2, the upper contact element 40 comprises a plurality of superimposed layers of n-doped polycrystalline silicon, which have a doping level that increases toward the input conduction means 51, so as to form a doping gradient that increases from the quantum well structure 20 toward the input conduction means 51 (in the figure the symbols “n”, “n+”, “n++” indicate the progressively increasing level of doping), with the advantageous effect of minimizing the overlap of the electrical field with regions of high charge density.

Even more preferably, the upper contact element 40 also comprises a lower first layer of intrinsic polycrystalline silicon (not doped, indicated with “poly-Si”) which is therefore interposed between the layers of n-doped polycrystalline silicon and the quantum well structure 20.

Advantageously, the layers of polycrystalline silicon that make up the upper contact element 40 can be deposited monolithically with the technique known as Low Pressure Chemical Vapor Deposition (LPCVD), in accordance with the usual CMOS techniques (see for example: Franssila, S. (2010), “Introduction to microfabrication”, John Wiley & Sons, page 50 and following).

The low bandgap layers 22 of the quantum well structure 20 can be made of one or more CMOS materials, such as for example: silicon (Si), germanium (Ge), titanium (T), aluminum (Al), copper (Cu), tungsten (W), nickel (Ni), hafnium (Hf), tantalum (Ta) and their oxides and nitrides where they exist (for example: silicon dioxide (SiO₂), silicon nitride (Si₃N₄), titanium nitride (TiN), etc.).

Preferably, the low bandgap layers 22 are made of titanium nitride (TiNx) or of any compounds or alloys of titanium nitride based on other CMOS metals such as aluminum (Al), hafnium (Hf) or tantalum (Ta), and therefore preferred materials for the low bandgap layers 22 are: TiNₓ, TₓAl_{y}N_{z}, TₓHf_{y}N_{z}, TₓTa_{y}N_{z}, where the titanium dose is higher than that of the other metals.

According to the invention, the high bandgap layers (barriers) 21 of the quantum well structure 20 are made of a material chosen among oxides and nitrides of the following materials: silicon (Si), titanium (Ti), aluminum (Al), hafnium (Hf), tantalum (Ta).

Preferably, the high bandgap layers (barriers) 21 of the quantum well structure 20 are made of a material chosen only among the nitrides of the following materials: aluminum (Al), hafnium (Hf), tantalum (Ta) or alloys or compounds thereof with titanium in which the above mentioned metals (Al, Hf, Ta) are dominant; this implies preferred materials for the barriers like: TₓAl_{y}N_{z}, TₓHf_{y}N_{z}, TₓTa_{y}N_{z}, where the titanium dose is lower than that of the other metals. Even more preferably the high bandgap layers 21 are made of aluminum nitride (AlN).

The choice of the materials indicated above as preferred makes it possible to increase the difference in energy of the conduction bands between the materials of the well and of the barrier, and therefore to increase the maximum energy of the photon emitted, and, ultimately, it makes it possible to obtain emission in the near-infrared.

In more detail, the choice of the materials indicated above as preferred is doubly advantageous because:
a) with respect to the state of the art (in which materials III-V such as InP, GaAs, etc. are used), it makes it possible to obtain the emission of photons in the near-infrared;
b) with respect to solutions with wells made of silicon and barriers made of oxides of various materials, it makes it possible to obtain the quantum well structure 20 (MQW) with a single-reactor deposition technique such as sputter deposition, ALD, PECVD or LPCVD, according to CMOS techniques.

The above mentioned difference in energy of the conduction bands has been verified with suitable DFT simulations (reference: Engel, E. (2011). Density functional theory. Springer-Verlag Berlin).

The use of nitrides is therefore preferred both for the high bandgap layers 21 (barriers) and for the low bandgap layers 22 (wells): instead of using oxides like aluminum oxide or silicon oxide for the high bandgap materials, the choice of nitrides is advantageous because it makes it possible not to introduce oxygen into the deposition reactor. In fact, it has been found that the oxidation of metals and nitrides is one of the principal causes of the deterioration of their optical performance.

With regard to the alloys indicated above, the use of aluminum, hafnium or tantalum can be an alternative and advantageous solution with respect to the use of non-stoichiometric titanium nitride, because the respective nitrides are insulating and high-bandgap (example: if T₁Al₀N is conductive and T₀Al₁N is insulating, then we can expect a continuous transition toward the reciprocal compound for low concentration levels of the material present in a lower amount).

Furthermore, owing to the very nature of deposition processes (emission, contamination etc.), it may be difficult to obtain a pure nitride of titanium in the wells and of aluminum in the barriers.

In practice, therefore, the entire quantum well structure 20 is made exclusively of CMOS materials, such as, for example: silicon (Si), germanium (Ge), titanium (T), aluminum (Al), copper (Cu), tungsten (W), nickel (Ni), hafnium (Hf), tantalum (Ta) and preferably of nitrides of these elements, where they exist (for example: titanium nitride (TiN), aluminum nitride (AlN), etc.).

According to a solution that has been found to be optimal, at least the low bandgap layers 22 (quantum wells) are made of titanium nitride (TiNₓ), not necessarily stoichiometric, or of titanium aluminum nitride (TₓAl_{y}N), not necessarily stoichiometric.

The charge density in the low bandgap layers 22 can be varied by conveniently varying the ratio of Nitrogen (N) with respect to Titanium (T) in the TiN_{X} molecule: by increasing the amount of nitrogen with respect to stoichiometric TiN (N:T ratio 1:1), the charge density is decreased. Reducing the charge density serves to reduce optical losses, and therefore to reduce the threshold current, and ultimately to minimize the minimum operating power of the laser.

In general, by acting on the ratio of nitrogen to titanium it is possible to modify the charge density; this is particularly useful because a low charge density obtained with a high concentration of nitrogen makes it possible to lessen optical losses, while regions with an excess of electrons make it possible to create a reserve of electrons in the active region that makes it possible to give rise to the quantum cascade.

Decreasing the charge density obtains the advantageous effect of narrowing the spectral width of the emission band of the optical amplifier 1. In fact, a higher charge density widens the emission band owing to electron-electron interaction.

In practice, preferably, the quantum well structure 20 comprises an active portion and an injection portion. In the active portion, the titanium nitride of the low bandgap layers 22 is chosen with a composition that is such as to have an insulating behavior (by choosing an insulating phase of titanium nitride), i.e. without excess charge, so as to have intrinsic quantum wells; this is obtained for example with titanium nitride T₃N₄.

In the injection portion, the titanium nitride is composed so as to have a slight excess charge in some of the quantum wells, by using for example over-stoichiometric titanium nitride TiNₓ (x>1).

Therefore, preferably, in one or more of the low bandgap layers 22 (and even more preferably in most of them) the titanium nitride has a nitrogen/titanium ratio (N:T) that exceeds 1, and according to an optimal solution it has an N:T ratio equal to 4:3 i.e. T₃N₄.

The use of titanium nitride, in combination with the use of a high bandgap material for the barriers (like aluminum nitride) is particularly advantageous in that it makes it possible to obtain the emission of a laser radiation with smaller wavelengths with respect to quantum cascade lasers in the background art made of materials III-V, and in particular wavelengths in the near-infrared that are compatible with telecommunications technologies. In the preferred embodiments, the spectrum of the obtainable emission wavelengths is comprised between 1110 nm (absorption of silicon) and 1700 nm (absorption of silica).

Furthermore, since the wavelength emitted in an interband transition in a quantum well is due to the energy difference between two confined states, such wavelength can be calibrated by modifying the thickness of the quantum well.

If possible, but not necessarily, the ratio between Nitrogen (N) and Titanium (T) is greater than 1 even when the titanium nitride is used in an alloy or in combination with the other metals indicated.

What was said for titanium nitride also applies to titanium aluminum nitride (TₓAl_{y}N), in particular with reference to the advantage of not introducing oxygen into the deposition reactor so as to prevent the oxidation of metals and nitrides and the consequent deterioration of optical performance.

FIG. 5 shows the simulated eigenfunctions in a well of titanium nitride associated with barriers of aluminum nitride in a quantum well structure 20 of the optical amplifier 1 provided according to the present invention (the graph shows the squared modulus |Ψᵢ|² of the indicated eigenfunctions).

FIG. 6 shows the transition energy between the first and the second confined state, i.e. the energy of the emitted photon, as a function of the thickness of a quantum well of titanium nitride with barriers of aluminum nitride. In the diagram of FIG. 6 it is evident that it is possible to emit in the near-infrared.

FIG. 7 is a graph showing the minibands with photon emission (arrow pointing downward indicated with hv) in the quantum well structure 20, of a preferred embodiment of the optical amplifier 1, with an emitter with three wells (with wells of titanium nitride and barriers of aluminum nitride), in which two periods of the super-grating can be seen. The graph shows the squared modulus |Ψᵢ|² of the indicated eigenfunctions. As can be seen from the figure, the thicknesses in nanometers are 0.5, 2.12, 1.6, 1.32, 1.14, 1.0, 0.89, 0.82 for the low bandgap layers 22 (the wells) and 0.5, 0.9, 0.8, 0.9, 1., 1.1, 1.1 for the high bandgap layers 21 (the barriers); the periods are separated by a barrier 1.5 nanometers thick. The simulated wavelength of the emitted photon is equal to 1550 nm.

FIG. 8 is a graph showing the flat cross-section of part of the optical amplifier of FIG. 7 (in particular the upper contact element 40, the quantum well structure 20, the upper layer of crystalline silicon 31 of the silicon-on-insulator substrate 30 that acts as a waveguide, the underlying insulating layer 32 and the containment insulating layer 60), with graphic indication of the intensity of the electrical field of the basic TM (transverse magnetic) mode. Such electrical field is obtained with 20 periods of the super-grating of FIG. 7, and an upper contact element 40 with layers of polysilicon with an increasing doping gradient simulated at 1550 nm with waveguide width of 350 nm and thicknesses of the layers of polysilicon of 0.5 μm, 0.5 μm, 1 μm and 1 μm for the intrinsic layer, n, n+ and n++, respectively. The layers of polysilicon n, n+ and n++ are doped with a concentration of donor atoms equal to 10¹⁶ cm⁻³, 10¹⁸ cm⁻³ and 10²⁰ cm⁻³, respectively. The thickness of the layer (the waveguide) of silicon on insulation 31 is 300 nm and the thickness of the lateral lobes is 100 nm.

On looking at the reference numerals in FIGS. 7 and 8, the correspondence with the parts of the general structure of the optical amplifier illustrated overall in FIGS. 1 and 2 is clear.

In the preferred embodiments, including those illustrated, the quantum well structure 20, the upper contact element 40 and part of the input conduction means 51 and of the output conduction means 52, 53 are included in a containment insulating layer 60, preferably made of silicon dioxide (SiO₂). Note that the input conduction means 51 and the output conduction means 52, 53 extend with their internal portion 51B, 52B, 53B inside the containment insulating layer 60, while the connecting ends 51A, 52A, 53A remain free outside.

The fact that both the silicon-on-insulator substrate 30 and the quantum well structure 20 (and preferably also the upper contact element 40) are made only of CMOS materials that are compatible with manufacturing methods in traditional electronics has undoubted advantages in terms of economy and of ease of manufacture: the entire optical amplifier 1 can be manufactured in a single manufacturing process (CMOS manufacturing method) in the production front-end, without the need to couple slices of different material in post-production.

In other words, the optical amplifier 1, according to the invention, can be produced by providing a monolithic growth on silicon substrate: the amplifier is advantageously integrated on a silicon substrate with a single process.

In particular, the low bandgap layers 22 (wells) and the high bandgap layers 21 (barriers) can be deposited monolithically with sputter deposition, ALD (Atomic Layer Deposition), PECVD (Plasma Enhanced Chemical Vapor Deposition), or LPCVD (Low Pressure Chemical Vapor Deposition), according to the usual CMOS techniques.

Furthermore, after a reactor is chosen, the CMOS nitrides listed previously as preferred can be deposited monolithically on the substrate with the same machine (sputter deposition, ALD, PECVD, LPCVD). This makes it possible to deposit the entire quantum well structure 20 with a single process; choosing nitrides only makes it possible to avoid introducing oxygen into the deposition chamber, which is known to reduce the optical performance of titanium nitride.

The electrical conduction means 51, 52, 53 and the metalization if any can also be done according to traditional techniques and processes of CMOS electronics.

Furthermore, the optical amplifier, according to the invention, makes it possible to obtain a low threshold current required to actuate the laser action, in particular by virtue of the silicon structure that forms a passive waveguide, characterized by lower optic propagation losses than those, for example, of InP at telecommunications wavelengths, as well as the possibility of providing lateral contacts as in the embodiment shown.

The operation of the optical amplifier 1 is clear and evident from the foregoing description.

In substance, during operation, the electrical conduction means 51, 52, 53 are connected to a current source, so as to generate a current inside the quantum well structure 20: a stream of electrons flows from the input electrical conduction means 51, through the upper contact element 40 and then through the quantum well structure 20, and then, from there, through the lower contact layer 31 up until the output electrical conduction means 52, 53. When the current has a value higher than a threshold value, the optical amplifier emits, in particular from the quantum well structure 20, the luminous radiation adapted to form the output laser beam. The emission occurs transversely, along an axis perpendicular to the cross-sectional plane of FIGS. 1 and 2.

Obviously in order to obtain a laser beam it is necessary to associate the optical amplifier 1 with a feedback mechanism, such as for example an optical resonator, which can be provided as it is in conventional semiconductor lasers.

The present invention therefore also relates to a laser device 100, 200 which comprises an optical amplifier 1, according to the invention, and an optical feedback (or resonance) system 170, 180, 190, 280 which is configured to amplify and filter the luminous radiation emitted by the optical amplifier 1. In other words, the optical amplifier constitutes the active element of the laser device 100, 200, while the optical resonance system supplies the feedback mechanism.

FIGS. 3 and 4 schematically show two possible, non-limiting embodiments of the laser device, indicated with the reference numerals 100 and 200.

In the embodiment of FIG. 3, the laser device 100 is provided as a DBR (distributed Bragg reflector) laser, in which the optical feedback system comprises a pair of mutually opposite reflector elements 180, 190 (Bragg reflectors) which define a resonating cavity between them in which the optical amplifier 1 is located. One of the reflector elements 180 is partially transparent to the emitted radiation and acts as an output reflector 180 from which the laser beam L exits. Conveniently, a phase modulation element 170 is also inserted in the cavity and serves to modulate the phase of the field in the cavity.

In the embodiment of FIG. 4, the laser device 200 is provided as a DFB (Distributed Feed Back) laser, in which the optical feedback system is formed by providing, in a known manner and directly in the optical amplifier 1, a periodic structure 280, for example a corrugated layer, which creates a periodic perturbation in the refractive index.

A waveguide made of silicon 290 extends from the optical amplifier 1.

In any case it is possible to provide the laser device by associating the optical amplifier 1 with other, conventional optical feedback systems, like a Fabry-Pérot resonator, a ring resonator, or adapted filters.

In practice it has been found that the optical amplifier, according to the present invention, achieves the intended aim and objects in that it is simpler and more economic to provide with respect to the background art.

Another advantage of the optical amplifier, according to the invention consists in that it has a larger spectrum of emission wavelengths with respect to conventional quantum cascade lasers, including emission wavelengths that are compatible with current telecommunications technologies.

Another advantage of the optical amplifier, according to the invention, consists in that it offers greater efficiency and more versatility with respect to the background art.

The optical amplifier, thus conceived, is susceptible of numerous modifications and variations, all of which are within the scope of the appended claims.

Moreover, all the details may be substituted by other, technically equivalent elements.

The disclosures in Italian Patent Application No. 102022000016356 from which this application claims priority are incorporated herein by reference.

Where the technical features mentioned in any claim are followed by reference numerals and/or signs, those reference numerals and/or signs have been included for the sole purpose of increasing the intelligibility of the claims and accordingly, such reference numerals and/or signs do not have any limiting effect on the interpretation of each element identified by way of example by such reference numerals and/or signs.

1-15. (canceled)

16. A semiconductor optical amplifier for laser devices, particularly of the quantum cascade type, which is adapted to emit luminous radiation when subjected to an electric current and which comprises:
a quantum well structure, composed of high bandgap layers alternated with low bandgap layers, which is interposed between a lower contact layer and an upper contact element;
input electrical conduction means and output electrical conduction means which are configured to allow a flow of an electric current through said quantum well structure;
and further comprising a silicon-on-insulator substrate which comprises an upper layer of crystalline silicon, said upper layer of crystalline silicon constituting said lower contact layer,
and wherein said high bandgap layers of the quantum well structure are made of a material chosen among oxides and nitrides of the following materials: silicon (Si), titanium (Ti), aluminum (Al), hafnium (Hf), tantalum (Ta).

17. The optical amplifier according to claim 16, wherein said low bandgap layers of the quantum well structure are made of titanium nitride or of titanium aluminum nitride.

18. The optical amplifier according to claim 16, wherein said low bandgap layers are made of an alloy of titanium nitride with hafnium (Hf) or tantalum (Ta) or aluminum (Al), such as TₓAl_{y}N_{z}, TₓHf_{y}N_{z}, TₓTa_{y}N_{z}, in which titanium is dominant.

19. The optical amplifier according to claim 18, wherein one or more of said low bandgap layers is made of titanium nitride with a nitrogen/titanium ratio greater than 1.

20. The optical amplifier according to claim 16, wherein said high bandgap layers are made of a material chosen among nitrides of: aluminum (Al), hafnium (Hf), tantalum (Ta), or of an alloy or compound of one of said nitrides of aluminum (Al), hafnium (Hf) or tantalum (Ta) with titanium, such as TₓAl_{y}N_{z}, TₓHf_{y}N_{z}, TₓTa_{y}N_{z}, wherein the titanium component is smaller than that of the other metals.

21. The optical amplifier according to claim 16, wherein said high bandgap layers are made of aluminum nitride.

22. The optical amplifier according to claim 16, wherein said quantum well structure comprises, in the low bandgap layers, Ti₃N₄ and TiNₓ with x>1.

23. The optical amplifier according to claim 16, wherein said upper layer of crystalline silicon comprises:
a central contact region which is in contact with said quantum well structure, and
at least one peripheral region which is adjacent to said central region, which is in contact with the output electrical conduction means and is constituted by n-doped silicon.

24. The optical amplifier according to claim 23, wherein said central contact region is made of n-doped silicon having a minimum percentage of donor atoms, and said at least one peripheral region comprises n-doped silicon having a percentage of donor atoms that is higher than said minimum percentage.

25. The optical amplifier according to claim 24, wherein said at least one peripheral region comprises:
at least one first layer of n-doped silicon with a medium percentage of donor atoms which is adjacent to said central region, and
at least one second layer of n-doped silicon with a high percentage of donor atoms which is adjacent to said output conduction means,
so as to form a doping gradient that increases from the quantum well structure toward said output conduction means.

26. The optical amplifier according to claim 16, wherein said upper contact element is made of poly crystalline silicon.

27. The optical amplifier according to claim 26, wherein said upper contact element comprises a plurality of superimposed layers of doped polycrystalline silicon which have a doping level that increases toward said input conduction means, so as to form a doping gradient that increases from the quantum well structure toward said input conduction means.

28. The optical amplifier according to claim 27, wherein said upper contact element comprises a lower layer of intrinsic polycrystalline silicon which is interposed between said layers of doped polycrystalline silicon and said quantum well structure.

29. The optical amplifier according to claim 16, constituted by a single monolithic structure which is grown directly on said silicon-on-insulator substrate.

30. A laser device comprising an optical amplifier according to claim 16, and an optical feedback system which is configured to amplify and filter a luminous radiation emitted by the optical amplifier.
